(19) United States
(12) Patent Application Publication
(10) Pub. No.: US 2002/0002012 A1
(43) Pub. Date: Jan. 3, 2002

(54) BOARD CONNECTING CONNECTOR

(76) Inventor: CHIEKO TORII, SHIZUOKA (JP)

Correspondence Address: SUGHRUE MION ZINN MACPEAK & SEAS PLLC, 2100 PENNSYLVANIA AVENUE NW, WASHINGTON, DC, 20037

(21) Appl. No.: 09/464,086

(22) Filed: Dec. 16, 1999

(30) Foreign Application Priority Data
Dec. 21, 1998 (JP) 10-362074

(51) Int. Cl. H05K 1/00

(52) U.S. Cl. 439/625

(57) ABSTRACT

A board connecting connector (1) includes a connector housing (2) having an attachment portion (7). A circuit board (6) is inserted into opposing wall portions (17, 18) of the attachment portion (7). A terminal (3) is connected to a circuit (12) of the circuit board (6). The terminal (3) has an resilient contact portion (4) to be contacted to the circuit (12). One of the wall portions (17) of the attachment portion (7) includes an engagement projection (5) corresponding to an engagement hole (20) of the circuit board (6). A maximum outer diameter of the engagement projection (5) is larger than an inner diameter of the engagement hole (20). The one of the wall portions (17) of the attachment portion (7) is configured as a wall portion having a slit portion (23) so as to be half or more separated from the connector housing (2).

### BACKGROUND OF THE INVENTION

1. Field of the Invention

The present invention relates to a board connecting connector in which terminals protruded from a connector housing are brought into resilient contact with a circuit board.

The present application is based on Japanese Patent Application No. Hei. 10-362074, which is incorporated herein by reference.

2. Description of the Related Art

FIG. 4 shows an example of a related board connecting connectors. A board connecting connector 31 includes a female connector housing 32 made of synthetic resin and terminals 38 made of metal. Each of the terminals 38 has a tab-like contact portion 33 protruded within the female connector housing 32. The contact portions 33 are arranged substantially in parallel with a circuit board 34. Each of the terminals 38 further has a connecting portion 37 fixedly connected to a printed circuit (hereinafter merely called as a circuit) 35 on the circuit board 34 by solder 36.

A mating male connector housing (not shown) is inserted into the female connector housing 32 in parallel to the circuit board 34. Each of the terminals 38 is fixed to the base wall 39 of the female connector housing 32 by a press-fitting or an insert-molding, and then bent downward at that position slightly protruded from the base wall 39, and further bent so as to extend along the circuit board 34 in parallel thereto, thereby forming the connecting portion 37.

The aforementioned connector thus arranged is a so-called “SMT” (surface mount type) wherein the connecting portion 37 is fixed to the front surface of the circuit board 34 by the solder 36. As another type of the board connecting connector, there is known a through hole type wherein the connecting portion 37 is not bent but passed through a hole of the circuit board 34 and connected to the rear surface of the circuit board 34 by soldering.

FIG. 5 shows another example of the related board connecting connectors, and the similar configuration is, for example, disclosed by Unexamined Japanese Utility Model Publication No. Sho. 63-65978.

In FIG. 5, a board connecting connector 41 includes a pair of left and right attachment portions 44, 44 for fixing a female connector housing 42 to a circuit board 43 so that the female connector housing 42 is directed upward, and terminals 45 downwardly protruded from the lower side of the female connector housing 42. The connecting portions formed at the tips of the terminals 45 are fixedly connected to the pad portions 48 of a circuit 47 formed on the front surface of the circuit board 43 by soldering (not shown).

Each of the attachment portions 44 is formed in a substantially U-shaped manner in its cross-section and continues to the side wall 49 of the female connector housing 42 so as to be integrally formed therewith. The circuit board 43 has a portion received within the attachment portions 44. The connecting portions 46 of the terminals 45 are formed by bending the tip portions of the terminals at a substantially right angle along the circuit board 43 and have flat surfaces brought into contact with to the pad portions 48 of the circuit 47, respectively. Each of the terminals 45 has a female type contact portion (not shown) accommodated in the female connector housing 42.

As shown in FIG. 6, engagement projections 50 are respectively disposed within the attachment portions 44, and correspondingly to the engagement projections 50, engagement holes 51 are respectively formed in the circuit board 43. The inner diameter of the engagement holes 51 is set to be larger than the outer width of the engagement projections 50. In order to surely insert the circuit board 43 into the attachment portions, a small clearance 52 is formed between the attachment portions 44 and the circuit board 43 in the thickness direction of the circuit board 43.

When the circuit board 43 is inserted into the attachment portions 44, the circuit board 43 advances beyond the engagement projections 50 while causing the lower walls 54 of the attachment portions 44 to flex. Then, the engagement projections 50 engage with the engagement holes 51 for positioning the board connecting connector 41 so that the board connecting connector 41 is fixed to the circuit board 43. Afterwards, the connecting portions 46 are fixed to the pad portions 48 by soldering, respectively.

However, the aforementioned terminals 38, 45 are connected to the circuit board 43 by the solder generally containing Pb, and therefore there may be encountered a problem that, when disposing of their wastes after being used, they cause environmental pollution. Further, at the time of performing maintenance of the connector such as repair or the like, there may be encountered problems that much operations such as removal of the solder, re-soldering or the like are required, and further the assembling operation of the connector is troublesome. Furthermore, at the time of contacting the connecting portions 37, 46 of the terminals 38, 45 to the circuit 35 or the pad portions 48, there may be encountered a problem that, when the circuit boards 34, 43 or the terminals 38, 45 are old, the electric conductivity between the circuit boards 34, 43 and the terminals 38, 45 becomes low and therefore the contact resistance thereof is large, thereby generating heat.

Furthermore, there is a problem in that, at the time of fixedly connecting the connecting portions 37, 46 of the terminals 38, 45 to the circuit 35 or the pad portions 48 by the solder in a state in which the female connector housings 32, 42 are fixed to the circuit boards 34, 43, the solder connecting portions are likely applied with stress due to thermal distortion. In particular, the board connecting connector 41 shown in FIG. 5 likely wobbles vertically (the thickness direction of the circuit board 43) due to the clearances 52 between the circuit board 43 and the attachment portions 44 as shown in FIG. 6, so that there is a chance that a clearance is generated between the connecting portions 46 of the terminals 45 and the pad portions 48 thereby to degrade the electrical contact property. For example, there is a possibility that the solder may be badly affected by the wobble at the time of the running of a vehicle to cause a crack or the like therein. The clearance between the connecting portions 46 and the pad portions 48 may also be generated due to the uneven sizes of the protruded lengths of the terminals 45, the thickness of the circuit board 43, the position of the attachment portions 44 or the like, due to the warp of the circuit board 43, or due to the degradation of the parallel relation between the upper wall 53 of the attachment portion 44 and the lower wall 54 caused by the distortion or warp thereof.

### SUMMARY OF THE INVENTION

Accordingly, an object of the present invention is to provide a board connecting connector which can eliminate the aforementioned problems of the related art, can easily perform the assembling, disposal and maintenance operations, does not cause wobble as to a circuit board, and can provide good electrical contact property.

To achieve the above object, according to the first aspect of the present invention, there is provided a board connecting connector which comprises a connector housing including a terminal which has a resilient contact portion, and an attachment portion which includes opposing wall portions between which a portion of a circuit board is received, the circuit board having a circuit, wherein the resilient contact portion of the terminal is resiliently contacted with the circuit of the circuit board.

Further, according to the second aspect of the present invention, it is effective that the board connecting connector further comprises an engagement projection provided between the opposing wall portions and formed on one of the opposing wall portions, wherein the portion of the circuit board, that is received between the opposing wall portions, has an engagement hole formed therein, and the engagement hole is engaged with the engagement projection, and wherein a maximum outer diameter of the engagement projection is larger than an inner diameter of the engagement hole.

Furthermore, according to the third aspect of the present invention, it is more effective that a slit is formed between the connector housing and the one of the wall portions having the engagement projection.

Furthermore, according to the fourth aspect of the present invention, it is more effective that the wall portions are partially connected to the connector housing at a portion of the one of the wall portions having the engagement projection.

Furthermore, according to the fifth aspect of the present invention, it is more effective that the attachment portion is formed into a cantilever-like manner with respect to the connector housing.

### BRIEF DESCRIPTION OF THE DRAWINGS

FIG. 1 is an exploded perspective view showing an embodiment of a board connecting connector according to the present invention;

FIG. 2 is a longitudinal sectional view showing a state in which an attachment portion of the board connecting connector is engaged with a circuit board;

FIG. 3 is a perspective view showing a connection state between the board connecting connector and the circuit board;

FIG. 4 is a longitudinal sectional view showing an example of a related board connecting connectors;

FIG. 5 is a perspective view showing another example of the related board connecting connectors; and

FIG. 6 is a longitudinal sectional view showing a state in which an attachment portion is engaged with a circuit board in the related board connecting connector.

### DETAILED DESCRIPTION OF THE PREFERRED EMBODIMENT

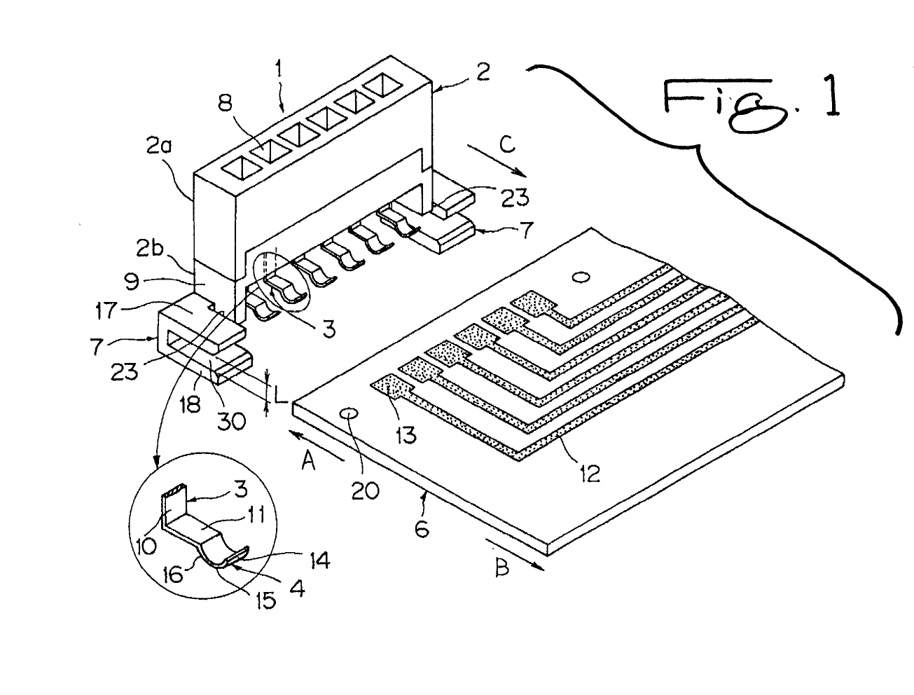

A preferred embodiment of the present invention will be described with reference to FIGS. 1 to 3.

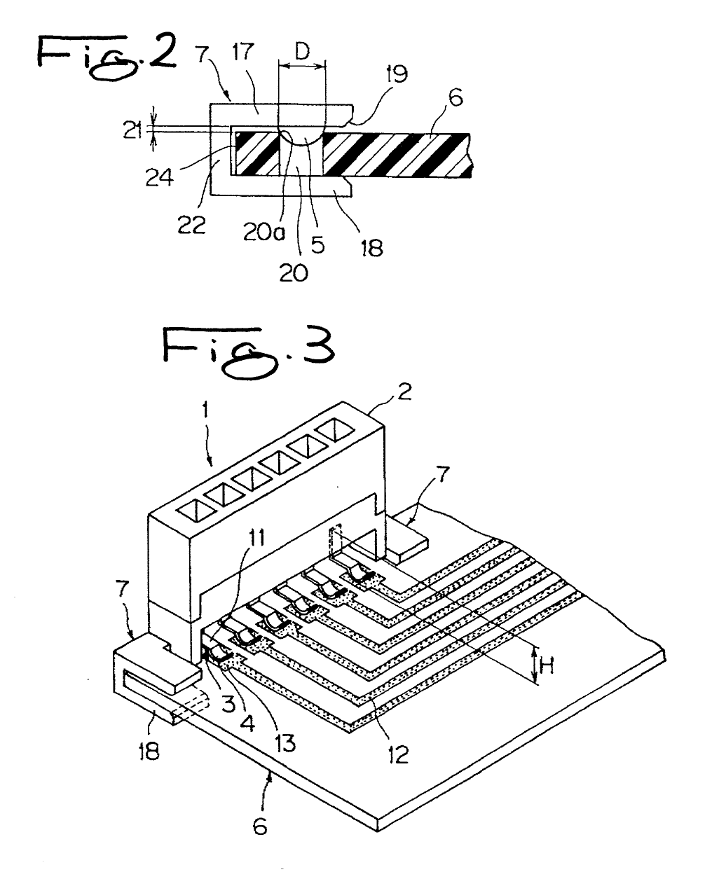

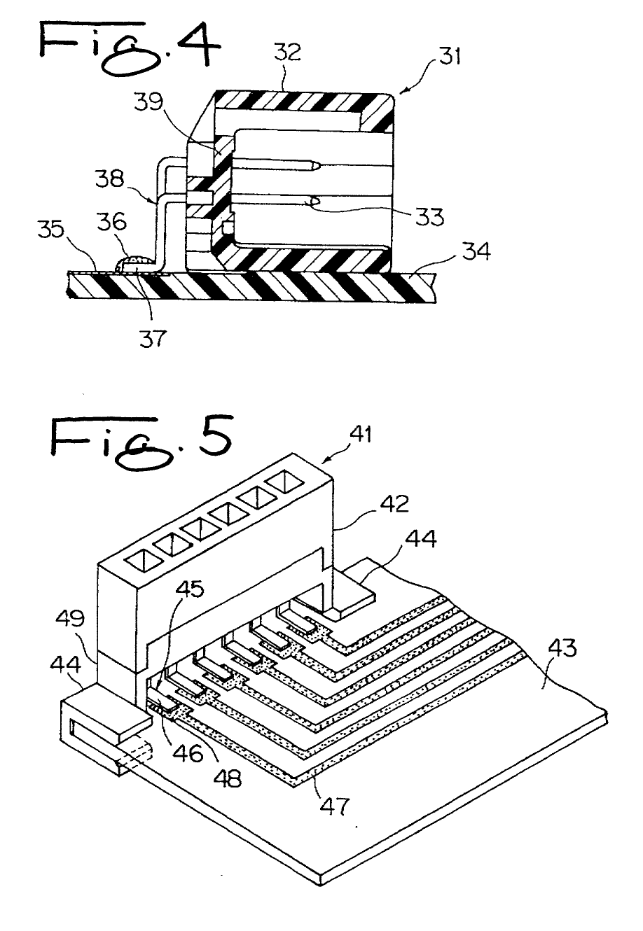

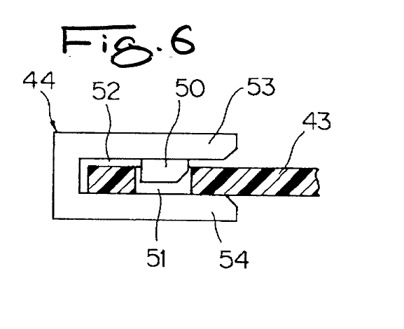

As shown in FIG. 1, a board connecting connector 1 includes a male connector housing (connector housing) 2 made of synthetic resin, the male connector housing 2 being upwardly directed, terminals 3 downwardly protruded from the male connector housing 2 and having curved resilient contact portions 4 at the tip ends thereof, and a pair of attachment portions (brackets) 7, 7 formed on the both sides of the male connector housing 2. The attachment portions 7, 7 have engagement projections 5 (see FIG. 2) formed in a hemisphere manner. A circuit board 6 is inserted into and engaged with the attachment portions 7, 7.

The male connector housing 2 is able to be divided into two portions, that is, an upper-side housing portion 2a and a lower-side housing portion 2b. The upper-side housing portion 2a has a plurality of terminal receiving chambers 8 directed upward, and fixed to the lower-side housing portion 2b. For example, the terminals 3 are insert molded in the lower-side housing portion 2b in such a manner that lower portions of the terminals 3 are protruded from the lower-side housing portion 2b. Female-type electric contact-portions (not shown), which correspond to the upper portions of the terminals 3, are respectively accommodated in the terminal receiving chambers 8. The attachment portions 7 are formed integrally with the both side walls 9 of the lower-side housing portion 2b so as to protrude therefrom, respectively.

The lower portion of each of the terminals 3 has a flat-plate-like straight portion 10 extending vertically, and a supporting portion 11 bent at a substantially right angle from the lower end of the straight portion 10 and horizontally extending in a detaching direction of the circuit board 6 (see an arrow B indicated in FIG. 1) to form a step portion. The resilient contact portion 4 extends downward from the front end of the supporting portion 11 so as to be curved in a substantially U-shape. However, the resilient contact portion 4 may have any other shape, and therefore, the resilient contact portion 4 may have, for example, a substantially J-shape, a substantially arc shape or the like instead of the substantially U-shape. Each of the supporting portions 11 is able to resiliently flex when a strong pressing force is upwardly applied thereto, and act to increase flexural rigidity of the corresponding resilient contact portion 4.

Each of the resilient contact portions 4 is brought into line-contact or face-contact with the corresponding conductive pad portion 13 continuing to the printed circuit 12, an electric wire (not shown) or the like. Such a circuit as the printed circuit 12, the electric wire or the like is merely called a “circuit” in this description hereinafter. In short, each of the pad portions 13 may continue to any electric conductor. Incidentally, the direction of the line contact is perpendicular to an inserting direction of the circuit board 6 (see an arrow A indicated in FIG. 1). Each of the resilient contact portions 4 is able to resiliently flex upwardly and downwardly.

Each of the resilient contact portions 4 of this embodiment includes a slanted guide portion 14 formed at the front end portion thereof to be slightly slanted forwardly, an arc-shaped contact surface portion 15 continuing to the slanted guide portion 14, and a base portion 16 rising from the contact surface portion 15 and continuing to the supporting portion 11.

The circuit board 6 can be easily inserted into the attachment portions 7, 7 as each of the resilient contact portions 4 has the slanted guide portion 14. At the time of this insertion of the circuit board 6, the base portion 16 and the supporting portion 11 suppress the deformation of the resilient contact portion 4 in the rear direction. Further, at the time of the insertion of the circuit board 6, the contact surface portion 15 of the resilient contact portion 4 strongly wipes the surface of the corresponding pad portion 13 of the circuit 12 (wiping function), thereby surely removing the oxide film of the corresponding pad portion 13 so as to improve the electrical contact property. Of course, this wiping function can be attained when the circuit board 6 is detached. The wiping function can also be attained by the resilient contact portion (4) having a U-shape or an arc-shape. It is also possible to slide and engage the board connecting connector 1 with the circuit board 6 as an arrow C (see FIG. 1) in place of inserting the circuit board 6 into the board connecting connector 1.

As shown in FIG. 2, each of the attachment portions 7 is formed in a substantially U-shaped configuration in its cross-section, and includes an upper wall (one wall portion) 17, a rear wall (coupling wall) 22 and a lower wall (the other wall) 18. Furthermore, each of the attachment portions 7 includes an insertion groove (insertion space) 30 in which the circuit board is slid and inserted. The insertion groove 30 extends horizontally between the upper wall 17 and the lower wall 18 opposing to each other. Further, each of the attachment portions 7 includes an engagement projection 5 having arc shape in its cross section or hemisphere shape on the inner surface of the upper wall 17.

In this embodiment, each of the engagement projections 5 is formed integrally with the corresponding attachment portion 7 made of synthetic resin. Each of the attachment portions 7 includes at the lower wall 18 thereof a mold-drawing hole (not shown) relative to the engagement projection 5. It is possible to attach a separate engagement projection (5) made of metal etc. to the attachment portion 7. Each of the upper wall 17 and the lower wall 18 has a tapered guide face 19 at the inner side of the tip end thereof so that the circuit board 6 is easily inserted.

The circuit board 6 includes circular engagement holes 20 for respectively receiving the engagement projections 5. The outer diameter (maximum outer diameter) D of each of the engagement projections 5 is set to be larger than the inner diameter of each of the engagement holes 20. A clearance 21 is formed between the upper surface of the circuit board 6 and the upper wall 17. Each of the engagement projections 5 abuts against the edge portion 20a of the corresponding engagement hole 20 at an intermediate portion of the hemisphere or arc surface in height thereof. In this state, the lower surface (rear surface) of the circuit board 6 abuts against the inner side surfaces of the lower walls 18 of the attachment portions 7. In other words, the circuit board 6 is pressed against the lower wall 18 of the attachment portions 7 by the engagement projections 5 and so fixed to the circuit board without being wobbled. The front end 24 of the circuit board 6 may be abutted against the rear walls 22 of the attachment portions 7 or may be arranged to have a slight clearance between the front end 24 and the rear walls 22.

In FIG. 1, slit portions 23 are respectively formed through a notching process between the upper walls 17 of the attachment portions 7 and the side walls 9 of the lower-side housing portion 2b so that those portions of the upper walls 17 coupled to the side walls 9 are half or more separated from the side walls 9. In other words, the attachment portions 7 are partially connected to the side walls 9 at the coupled portions of the upper walls 17. Accordingly, the upper walls 17 have flexibility and elasticity in the thickness direction. Therefore, the attachment portions 7 may be respectively formed into a cantilever-like manner with respect to the lower-side housing portion 2b through the coupled portions of the upper walls 17. When the circuit board 6 is inserted into the insertion grooves 30 of the attachment portions 7, the front end 24 of the circuit board 6 abuts against the engagement projections 5 so that the upper walls 17 upwardly flex, and then the engagement projections 5 engages with the engagement holes 20 to push the circuit board 6 toward the lower walls 18 so that the upward flexion of the upper walls 17 are restored.

Since the upper walls 17 can elastically flex in the thickness direction thereof, even if there is the warp of the circuit board 6, the degradation of the parallel relation between the upper wall 17 and the lower wall 18 of the attachment portion 7, the unevenness of the thickness of the circuit board 6 and the unevenness of the size of the distance L etc. between the upper wall 17 and the lower wall 18 of the attachment portion 7, such warp, unevenness of the thickness, unevenness of the size can be absorbed and therefore the wobble can be surely prevented.

Although the lower walls 18 are not coupled to the side walls 9 of the lower-side housing portion 2b, the upper walls 17 are more flexible than the lower walls since the width of each of the upper walls 17 is smaller than that of each of the lower walls by the notched length of the slit portions 23. In this manner, since the upper walls 17 upwardly flex so as to absorb the unevenness of the size and the circuit board 6 is fixed horizontally along the lower walls 18 with a relatively high rigidity of the attachment portions 7, the male connector housing 2 can be positioned perpendicularly without being inclined. Thus, the perpendicular relation of the male connector housing 2 with respect to the circuit board 6 can be maintained accurately and therefore the fitting accuracy of the male connector housing relative to a mating female connector housing (not shown) can be improved.

Further, since the width of the upper walls 17 of the attachment portions 7 is relatively small, the upper walls 17 can also be flexed in the width direction slightly, so that the positional error in the width direction of the upper walls 17 between the pair of left and right engagement projections 5 and the engagement holes 20 can be absorbed, whereby the engagement projections can be surely retained by the engagement holes. Each of the hemisphere-like engagement projections 5 performs the centripetal action relative to the corresponding engagement hole 20, so that the positioning between the pad portions 13 and the resilient contact portions 4 can be performed accurately.

The configuration of each of the engagement projections 5 is not limited to the hemisphere shape or the arc shape, and each of the engagement projections may be configured in a conical shape or a pyramid shape so long as the engagement projections can perform the centripetal action. In this connection, tip portions of the engagement projections of conical shape or the pyramid shape may be truncated horizontally with respect to the upper walls 17 so as to prevent the engagement holes from being extremely caught by such the engagement projections.

As shown in FIG. 3, the resilient contact portions 4 of the terminals 3 are brought into resiliently contact with the pad portions 13 of the circuit 12 while the circuit board 6 is slid in and engaged with the pair of attachment portions 7, 7. The resilient contact portions 4 are pressed to the corresponding pad portions 13 with a strong contact pressure according to the configuration shown by the enlarged view of FIG. 1. As a result, the terminals 3 can be connected to the circuit 12 surely, simply and stably without using solder, and therefore, the workability of the assembling operation of the connector can be improved.

Further, since the circuit board 6 is downwardly pressed by the resilient contact portions 4 and therefore urged against the lower walls 18 of the attachment portions 7, the occurrence of the wobble between the circuit board 6 and the board connecting connector 1 can be prevented. Such a technical merit can be attained without using the hemisphere-like engagement projections 5. However, at the time of using the hemisphere-like engagement projections, the degree of the wobble between the circuit board and the connector can be further suppressed by the multiplier effect of the pressing force by the engagement projections 5. Even if the length H (see FIG. 3) of those portions of the terminals 3 protruded from the lower-side housing portion 2b are uneven, since both the resilient contact portions 4 and the supporting portions 11 have flexibility, the unevenness of the size can be absorbed. Thus, the electrical contact can be surely performed and further the protruded length H of the terminals 3 may be managed roughly.

When the disposal operation, the maintenance operation or the like is performed, since the terminals 3 are fixed to the circuit board 6 without using solder, the circuit board 6 can be easily detached by drawing the circuit board 6 while fixing the board connecting connector 1, and therefore, the board connecting connector 1 and the circuit board 6 can be easily separated. Thus, the operation such as maintenance, recycle or the like can be made easier. Of course, since the toxic solder is not employed, the connector is useful for the environmental protection.

The detachment property of the circuit board 6 is further improved by using the hemisphere-like engagement projections 5 (FIG. 2). That is, since the upper wall 17 of the attachment portion 7 upwardly flexes while the arc-shaped surface of the engagement projection 5 slides smoothly along the edge portion 20a of the engagement hole 20 (see FIG. 2), the locking state between the engagement projection 5 and the engagement hole 20 can be relatively easily released.

As described above, according to the present invention, since the circuit board and the terminals are not connected by the solder but connected through the resilient contact therebetween, there does not arise an environmental problem due to toxic solder at the time of wasting the connector. Further, the assembling operation can be easily performed, and the decomposition of the connector can be easily performed at the time of the recycle or the maintenance, so that the working efficiency of such operation can be improved. Furthermore, at the time of insertion or separation of the circuit board, since the resilient contact portions wipe the circuit, the oxide film on the circuit is removed, and therefore the electrical contact property of the connector can be improved. Furthermore, since the circuit board is pressed toward the attachment portions by the spring force of the resilient contact portions, the wobble between the circuit board and the connector can be suppressed, so that the abrasion of the contact portions and the abrasion or scratch or the like between the circuit board and the attachment portions can be prevented.

Further, according to the present invention, since the engagement projections press the circuits board toward the other wall portions of the attachment portions, the wobble between the circuit board and the board connecting connector can be suppressed. Further, the abrasion of the contact portions and the abrasion or scratch or the like between the circuit board and the attachment portions can be further surely prevented by the multiplier effect of the pressing action of the resilient contact portions described above.

Still further, according to the present invention, since the wall portions resiliently flex, the circuit board can be easily inserted. Further, since the wall portions resiliently press the circuit board, the wobble can be surely prevented. Furthermore, since the warp of the circuit board and the unevenness of the sizes of the respective parts can be absorbed, the connector housing can be prevented from being inclined relative to the circuit board.

What is claimed is:

1. A board connecting connector, comprising a connector housing including a terminal which has a resilient contact portion, and an attachment portion which includes opposing wall portions between which a portion of a circuit board is received, the circuit board having a circuit,
wherein the resilient contact portion of the terminal is resiliently contacted with the circuit of the circuit board.

2. The board connecting connector of claim 1, further comprising an engagement projection provided between the opposing wall portions and formed on one of the opposing wall portions, wherein the portion of the circuit board, that is received between the opposing wall portions, has an engagement hole formed therein, and the engagement hole is engaged with the engagement projection, and wherein a maximum outer diameter of the engagement projection is larger than an inner diameter of the engagement hole.

3. The board connecting connector of claim 2, wherein a slit is formed between the connector housing and the one of the wall portions having the engagement projection.

4. The board connecting connector of claim 3, wherein the wall portions are partially connected to the connector housing at a portion of the one of the wall portions having the engagement projection.

5. The board connecting connector of claim 4, wherein the attachment portion is formed into a cantilever-like manner with respect to the connector housing.
